(19) United States
(12) Patent Application Publication
(10) Pub. No.: US 2010/0185909 A1
(43) Pub. Date: Jul. 22, 2010

(54) Asynchronous Scan Chain Circuit

(75) Inventors: Chien-Mo Li, Taipei (TW); Chi-Hsuan Cheng, Taipei (TW)

Correspondence Address: BEVER HOFFMAN & HARMS, LLP;901 Campisi Way, Suite 370, Campbell, CA, 95008, US

(73) Assignee: National Taiwan University, Taipei (TW)

(21) Appl. No.: 12/651,919

(22) Filed: Jan. 4, 2010

(30) Foreign Application Priority Data
Jan. 17, 2009 (TW) 098101848

(51) Int. Cl. G01R 31/3177; G06F 11/25

(52) U.S. Cl. 714/726; 714/E11.155

(57) ABSTRACT

Disclosed is a dual-rail asynchronous insensitive scan chain circuit designed for test. This scan chain does not require any clock even in scan mode, so it is truly an asynchronous design for testability. The normal function of the asynchronous scan chain can not be affected when removing any clock controls. The handshake protocols between two sequential elements used in the asynchronous scan chain become the scan chain transmission structure, rather than the timing control used in synchronous scan chain in the prior arts. Therefore, both in the function mode and scan mode, the scan chain always operates under the asynchronous condition. It not only can reach a complete test scanning, achieve high fault detection coverage and consume lower power, but also avoid the clock skew problem.

### FIELD OF THE INVENTION

The present invention relates to integrated circuits test, and more particularly, to a dual-rail asynchronous insensitive scan chain circuit designed for test.

### BACKGROUND OF THE INVENTION

As TFT technology is not yet mature, a thorough testing of TFT circuits is essential to make sure they are free of defects. Unfortunately, traditional design for testability (DFT), such as scan chains, is mainly for synchronous circuits with clocks. Without DFT, test pattern generation for asynchronous circuits is very difficult and fault coverage is unsatisfactory. So far, there is still insufficient research in DFT for asynchronous circuits.

Although the synchronous technology-based circuit plus some special automated instrument can be configured as an asynchronous circuit for test, the DFT of asynchronous circuits for thorough scan is still not mature. Specially designed test pattern generators are needed to produce the useful test pattern. Moreover, external clock to control the action of the scan circuit is needed. Thus, the clock skew would be the first problem existed in the system, the efficiency decreasing of the scan circuit would be the second and the large scale occupied would be the third.

Another design in prior art is to implement regional scan for reducing the above impact. However, a progressive automatic test pattern generator is also needed to generate the test pattern. The realized fault coverage detection rate becomes lower and the test time consumed gets longer.

According to the above drawback in the prior art, the applicant uses asynchronous handshaking circuit design to accomplish overall scan and reach high fault detection coverage rate without any clock control and affection in system operation. Thus the invention of the case “asynchronous scan chain circuit” would be the best way to solve the deficiencies of conventional means.

### SUMMARY OF THE INVENTION

The present invention provides a dual-rail asynchronous scan chain circuit, controlling the scan chain input test pattern and outputting the test outcome according to the handshake protocol between each two of scan units. The asynchronous scan chain circuit does not require any clock in functional or scan mode so it is a truly asynchronous design for testability (DFT). Furthermore, the present invention not only consumes very low power and avoids the clock skew problems, but also achieves high fault detection coverage.

According to an aspect of the present invention, there is provided a scan chain circuit operated according to a handshake protocol signal, and including: plural sequentially serially connected stage module circuits, which are alternatively connected in a connecting state under a functional mode and selectively connected at plural levels under a test scan mode, and each of which has: an output terminal providing a handshake protocol output signal for a subsequent one of the stage module circuits; an input terminal coupled to the output terminal of a preceding one of the stage module circuits under the functional mode; and the plural levels.

Preferably, each of the plural stage module circuits further comprises a 3-level unit circuit having a Muller C element having a first input terminal and a second input terminal, a first dual rail scan latch having an output terminal connected to the first input terminal of the Muller C element, and a second dual rail scan latch having an output terminal connected to the second input terminal of the Muller C element.

Preferably, the scan chain circuit further includes plural combinational logic circuits respectively coupled between two adjacent ones of the plural stage module circuits, wherein each of the plural combinational logic circuits receives an output signal from one of the first and the second dual rail scan latches of a preceding one of the two adjacent stage module circuits to provide an input signal for one of the first and the second dual rail scan latches of a subsequent one of the two adjacent stage module circuits.

Preferably, the handshake protocol output signal includes a handshake protocol output signal under the functional mode and a handshake protocol output signal under the test scan mode, and each of the first and the second dual rail scan latches further includes: two Muller C elements, each of which has a first input terminal, a second input terminal and an output terminal; a first, a second and a third multiplexers, each of which has a first input terminal receiving a first input signal, a second input terminal receiving a second input signal, a scan enable terminal receiving an enable input signal and an output terminal transmitting an output signal, wherein all the first, the second and the third multiplexers use the respective received first input signals as the respective output signals when the respective received enable input signals are 0, all the first, the second and the third multiplexers use the respective received second input signals as the respective output signals when the respective received enable input signals are 1, the output terminal of the first multiplexer is coupled to the first input terminals of the two Muller C elements, and the output terminals of the second and the third multiplexers are respectively coupled to the second input terminals of the two Muller C elements; and an exclusive-NOR gate having an input terminal coupled to the output terminals of the two Muller C elements of the first dual rail scan latch, and an output terminal providing the handshake protocol output signal under the test scan mode and coupled to the first input terminal of the Muller C element of the 3-level unit circuit and the second input terminal of the first multiplexer of one of the first and the second dual rail scan latches of the preceding one of the plural stage module circuits.

Preferably, the handshake protocol signal includes a handshake protocol signal under the functional mode and a handshake protocol signal under the test scan mode, the first and the second input signals of the first multiplexer respectively are the handshake protocol signal under the functional mode and the handshake protocol signal under the test scan mode, the first and the second input signals of the second multiplexer respectively are a data true input signal under the functional mode and a scan true input signal under the test scan mode, and the first and the second input signals of the third multiplexer respectively are a data false input signal under the functional mode and a scan false input signal under the test scan mode.

Preferably, the scan chain circuit is operated in the functional mode when the scan enable signals are 0 and being operated in the test scan mode when the scan enable signals are 1.

Preferably, the first and the second dual rail scan latches of the 3-level unit circuit of each of the plural stage module circuits receive the handshake protocol output signal provided from the subsequent one of the plural stage module circuits.

Preferably, each of the first and the second dual rail scan latches has a first and a second input terminals, each of the first input terminals of the first and the second dual rail scan latches receives a data input signal, and each of the second input terminals of the first and the second dual rail scan latches receives a scan input signal.

Preferably, each of the plural stage module circuits generates a state data according to the respective received handshake protocol output signals and shifts the respective state data to the preceding one of the plural stage module circuits under the functional mode, and the state data of a specific one of the plural stage module circuits is shifted to one of the plural levels of one of two stage module circuits adjacently connected to the specific stage module circuit under the test scan mode.

Preferably, the scan chain circuit is embedded in a chip.

Preferably, the scan chain circuit receives an input signal and the handshake protocol signal and providing an output signal according to the input signal and the handshake protocol signal.

According to another aspect of the present invention, there is provided a scan chain circuit receiving a handshake protocol signal, and including: plural sequentially serially connected stage module circuits, each of which has: an output terminal providing a handshake protocol output signal for a subsequent one of the stage module circuits; an input terminal coupled to the output terminal of an antecedent one of the stage module circuits under the functional mode; and the plural levels.

Preferably, the scan chain circuit further includes plural combinational logic circuits, wherein each of the plural stage module circuits further comprises a first and a second level circuits and a first and a second dual rail scan latches, the plural combinational logic circuits are respectively coupled between two adjacent ones of the plural stage module circuits, and each of the plural combinational logic circuits receives an output signal from one of the first and the second dual rail scan latches of an antecedent one of the two adjacent stage module circuits and provides an input signal for one of the first and the second dual rail scan latches of a subsequent one of the two adjacent stage module circuits.

Preferably, each of the plural stage module circuits further comprises a Muller C element having a first input terminal, a second input terminal and an output terminal providing the respective handshake protocol output signal for the antecedent one of the stage module circuits.

Preferably, the first level circuit is a first dual rail scan latch having an output terminal connected to the first input terminal of the Muller C element.

Preferably, the second level circuit is a second dual rail scan latch having an output terminal connected to the second input terminal of the Muller C element.

According to another aspect of the present invention, there is provided a scan chain circuit, including: plural stage module circuits, each of which provides a handshake protocol output signal for a preceding one of the plural stage module circuits.

Preferably, the scan chain circuit according is operated according to a handshake protocol signal.

Preferably, the plural stage module circuits are sequentially connected.

The foregoing and other features and advantages of the present invention will be more clearly understood through the following descriptions with reference to the drawings, wherein:

### BRIEF DESCRIPTION OF THE DRAWINGS

FIG. 1 is a block diagram showing the data flow of a dual-rail asynchronous pipeline circuit in functional mode.

FIG. 2 is a block diagram showing the data flow of a dual-rail asynchronous pipeline circuit in scan mode.

FIG. 3 is a diagram of a hazard-free multiplexer, wherein FIG. 3 (a) shows its schematic diagram, FIG. 3 (b) shows its circuit diagram.

FIG. 4 is a schematic diagram showing a dual-rail scan latch.

FIG. 5 is a circuit diagram showing a typical stitched scan chain of eight scan latches.

### DETAILED DESCRIPTION OF THE PREFERRED EMBODIMENT

The present invention will now be described more specially with reference to the following embodiments. It is to be noted that the following descriptions of preferred embodiments of this invention are presented herein for the purposes of illustration and description only; it is not intended to be exhaustive or to be limited to the precise form disclosed.

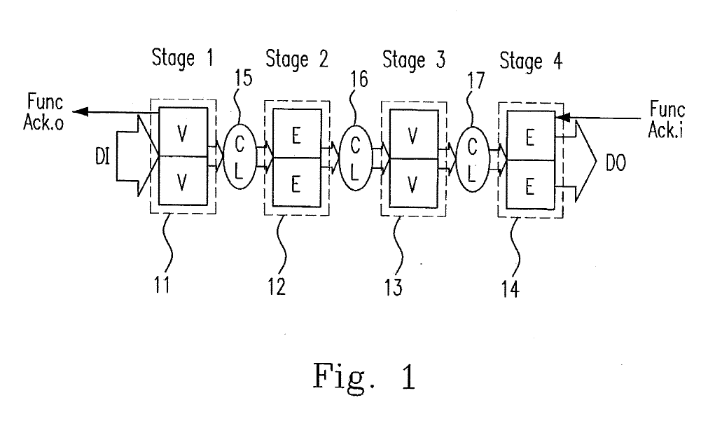

Please refer to FIG. 1, which is a block diagram showing the data flow of a dual-rail asynchronous pipeline circuit in functional mode. “DI” and “DO” are data inputs and outputs, respectively. “CL” stands for dual-rail combinational logic. The asynchronous pipeline circuit includes: a first stage 11, a second stage 12, a third stage 13, a fourth stage 14, a first combinational logic 15, a second combinational logic 16, a third combinational logic 17 and a fourth combinational logic 18. Each stage of the pipeline circuit consists of two latches. In functional mode, the odd stages latches (11,13) hold valid data, indicated by letter “V”, while the even stages latches (12,14) hold empty data, indicated by letter “E”. Whenever DO is acknowledged by the receiver, the data is propagated forward by a stage, that is, V's are replaced by E's and E's are replaced by V's. V and E always alternate so that data are preserved in correct order.

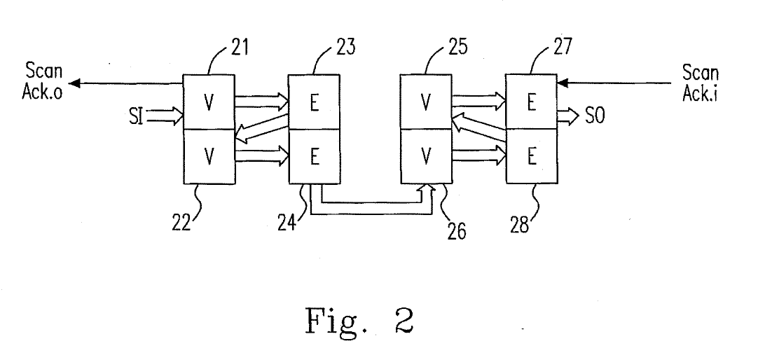

Please refer to FIG. 2, which is a block diagram showing the data flow of a dual-rail asynchronous pipeline circuit in scan mode. “SI” and “SO” are one-bit scan input and one-bit scan output, respectively. Whenever SO is acknowledged by the receiver, the data is propagated forward by a stage from SI to SO. In FIG. 2, the asynchronous pipeline circuit includes a first latch 21, a second latch 22, a third latch 23, a fourth latch 24, a fifth latch 25, a sixth latch 26, a seventh latch 27 and a eighth latch 28. The scan latches are stitched in an alternating way such that a “V scan latch” is always followed by an “E scan latch” and vice versa.

Testing the odd stages of CL is performed in the following sequence. First, the scan enable signal is asserted and the circuit enters scan mode as FIG. 2. The scan input patterns are shifted into the scan chain one by one. After all bits are shifted in position, valid data (V) are in odd stages latches and empty (E) are in even stages latches. Then the scan enable signal is de-asserted and the circuit enters functional mode as FIG. 1. The scan input patterns pass through the combinational logic and, after a certain amount of propagation time, valid responses become available. After the receiver acknowledge the data output, the valid responses are captured by the next (even) stage latches. The scan enable is again asserted and the circuit returns to scan mode. The captured responses are shifted out one bit by one bit. The captured responses are compared with expected value to determine whether the combinational logic is faulty or not. The even stages of combinational logic are tested in the similar way except that the valid data are now located in the even stage of latches, instead of odd stage of latches.

In a typical test scan mode, the seventh latch 27 receives a scan handshake protocol input signal (Scan.Ack.i) after outputting its empty data (E). Then, the fifth latch 25 receives a Scan.Ack.i signal from the seventh latch 27 after outputting its valid data (V). Then, the eighth latch 28 receives a Scan.Ack.i signal from the fifth latch 25 after outputting its empty data (E). Then, the sixth latch 26 receives a Scan.Ack.i signal from the eighth latch 28 after outputting its valid data (V). Then, the fourth latch 24 receives a Scan.Ack.i signal from the sixth latch 26 after outputting its empty data (E). Then, the second latch 22 receives a Scan.Ack.i signal from the fourth latch 24 after outputting its empty data (V). Then, the third latch 23 receives a Scan.Ack.i signal from the second latch 22 after outputting its empty data (E). Then, the first latch 21 receives a Scan.Ack.i signal from the third latch 23 after outputting its empty data (V).

Although the scan chain operates correctly, there is a potential problem of fault coverage loss. When testing a certain stage of combinational logic, the empty data “00” cannot be applied because V and E must alternate to make sure of a correct shift operation. For the example in FIG. 2, the first stage of latches cannot be empty. This results in fault coverage degradation (or untestable faults) in the combinational logic because the data “00” cannot be applied. To solve this problem, a new empty signal has to be created to replace the original empty data “00” in scan mode. Therefore, the scan empty data “11” can be used to make up the deficiency. In functional mode (FIG. 1), the functional empty data “00” are used to separate valid data between stages. However, in scan mode (FIG. 2), the scan empty data “11” is used to separate scan data between two consecutive scan latches. In this way, the functional data “00” is now a valid input to apply to the combinational logic so no fault coverage degradation is incurred.

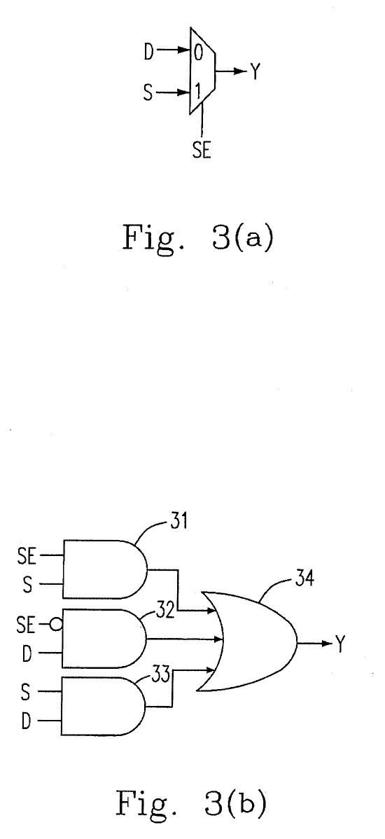

Please refer to FIG. 3 (a), which shows a schematic diagram of a hazard-free multiplexer. The input data D is led to output Y when scan enable control signal (SE) goes low (0), The input scan S is led to output Y when scan enable control signal goes high (1). FIG. 3 (b) shows a circuit diagram of a hazard-free multiplexer, which includes a first AND gate 31, a second AND gate 32, a third AND gate 33 and an OR gate 34. It acts as above described as FIG. 3 (a).

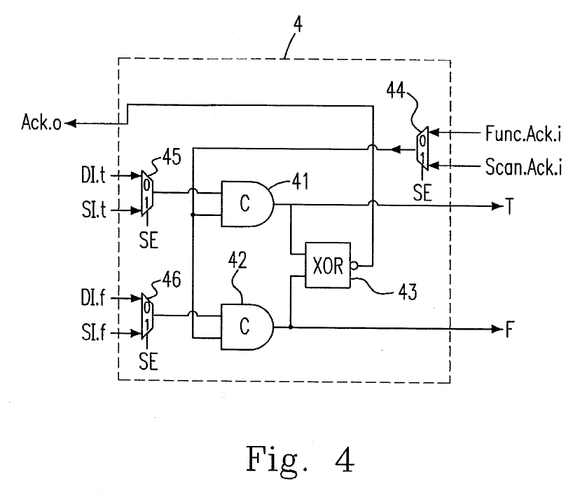

Please refer to FIG. 4, which is a schematic diagram showing a dual-rail scan latch 4. The dual-rail scan latch 4 has a first Muller C element 41, a second Muller C element 42, an XOR gate 43, a first multiplexer 44, a second multiplexer 45 and a third multiplexer 46. The first Muller C element 41 and the second Muller C element 42 are the progressive units in asynchronous scan chain circuit, used to store signals and use the output of the data completion detection circuit (XOR gate 43) as the control signal of the preceding stage circuit. The data completion detection circuit detects the data status and determines the output control signal according to the data status, transmitting the handshake protocol signal to the preceding stage circuit.

The dual-rail scan latch 4 employs the scan enable control signal (SE) to convert the transmission path between the normal functional mode and the test scan mode. In functional mode, the input data Data.in.t of the second multiplexer 45 and the Func.ack.i of the first multiplexer 44 are led to the input port of the first Muller C element 41, and the Data.in.f of the third multiplexer 46 and the Func.ack.i of the first multiplexer 44 are led to the input port of the second Muller C element 42 when scan enable control signal (SE) goes low (0).

In scan mode, the input data Scan.in.t of the second multiplexer 45 and the Scan.ack.i of the first multiplexer 44 are led to the input port of the first Muller C element 41, and the Scan.in.f of the third multiplexer 46 and the Scan.ack.i of the first multiplexer 44 are led to the input port of the second Muller C element 42 when scan enable control signal (SE) goes high (1).

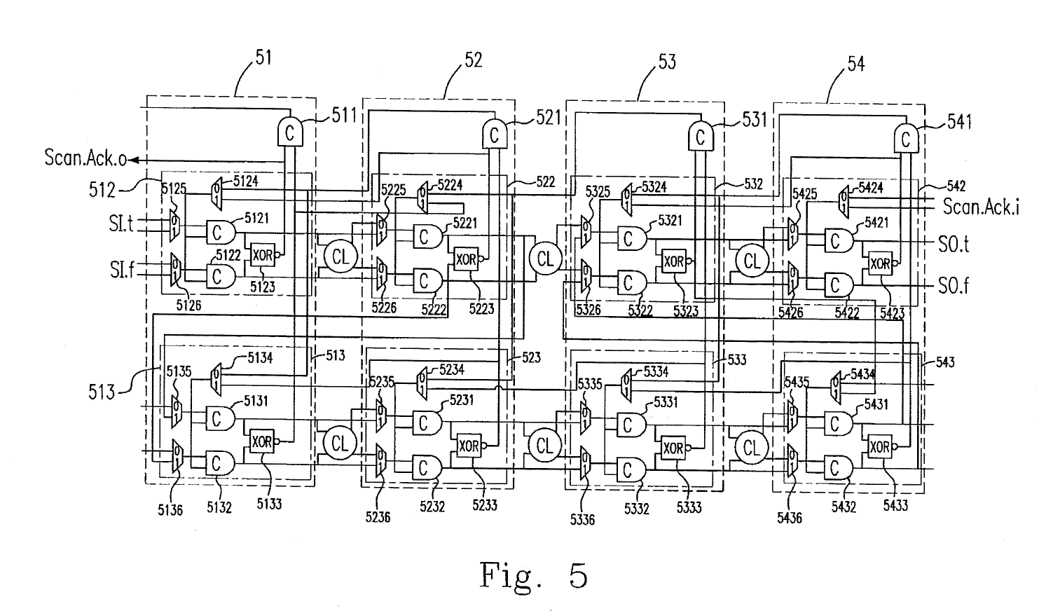

Please refer to FIG. 5, which is a circuit diagram showing a typical stitched scan chain of eight scan latches. This figure corresponds to the block diagram in FIG. 2. The multiplexers in the proposed scan latch must be hazard-free to avoid incorrect operation. The circuit includes a first stage module circuit 51, which is a 3-level unit circuit including a first stage Muller C 511 transmitting handshake protocol signal, a first stage first dual-rail scan latch 512, a first stage first dual-rail scan latch first Muller C 5121, a first stage first dual-rail scan latch second Muller C 5122, a first stage first dual-rail scan latch XNOR GATE 5123, a first stage first dual-rail scan latch first multiplexer 5124, a first stage first dual-rail scan latch second multiplexer 5125, a first stage first dual-rail scan latch third multiplexer 5126, a first stage second dual-rail scan latch 513, a first stage second dual-rail scan latch first Muller C 5131, a first stage second dual-rail scan latch second Muller C 5132, a first stage second dual-rail scan latch XNOR GATE 5133, a first stage second dual-rail scan latch first multiplexer 5134, a first stage second dual-rail scan latch second multiplexer 5135, a first stage second dual-rail scan latch third multiplexer 5136, a second stage module circuit 52, which is a 3-level unit circuit including a second stage Muller C 521 transmitting handshake protocol signal, a second stage first dual-rail scan latch 522, a second stage first dual-rail scan latch first Muller C 5221, a second stage first dual-rail scan latch second Muller C 5222, a second stage first dual-rail scan latch XNOR GATE 5223, a second stage first dual-rail scan latch first multiplexer 5224, a second stage first dual-rail scan latch second multiplexer 5225, a second stage first dual-rail scan latch third multiplexer 5226, a second stage second dual-rail scan latch 523, a second stage second dual-rail scan latch first Muller C 5231, a second stage second dual-rail scan latch second Muller C 5232, a second stage second dual-rail scan latch XNOR GATE 5233, a second stage second dual-rail scan latch first multiplexer 5234, a second stage second dual-rail scan latch second multiplexer 5235, a second stage second dual-rail scan latch third multiplexer 5236, a third stage module circuit 53, which is a 3-level unit circuit including a third stage Muller C 531 transmitting handshake protocol signal, a third stage first dual-rail scan latch 532, a third stage first dual-rail scan latch first Muller C 5321, a third stage first dual-rail scan latch second Muller C 5322, a third stage first dual-rail scan latch XNOR GATE 5323, a third stage first dual-rail scan latch first multiplexer 5324, a third stage first dual-rail scan latch second multiplexer 5325, a third stage first dual-rail scan latch third multiplexer 5326, a third stage second dual-rail scan latch 533, a third stage second dual-rail scan latch first Muller C 5331, a third stage second dual-rail scan latch second Muller C 5332, a third stage second dual-rail scan latch XNOR GATE 5333, a third stage second dual-rail scan latch first multiplexer 5334, a third stage second dual-rail scan latch second multiplexer 5335, a third stage second dual-rail scan latch third multiplexer 5336, a fourth stage module circuit 54, which is a 3-level unit circuit including a fourth stage Muller C 541 transmitting handshake protocol signal, a fourth stage first dual-rail scan latch 542, a fourth stage first dual-rail scan latch first Muller C 5421, a fourth stage first dual-rail scan latch second Muller C 5422, a fourth stage first dual-rail scan latch XNOR GATE 5423, a fourth stage first dual-rail scan latch first multiplexer 5424, a fourth stage first dual-rail scan latch second multiplexer 5425, a fourth stage first dual-rail scan latch third multiplexer 5426, a fourth stage second dual-rail scan latch 543, a fourth stage second dual-rail scan latch first Muller C 5431, a fourth stage second dual-rail scan latch second Muller C 5432, a fourth stage second dual-rail scan latch XNOR GATE 5433, a fourth stage second dual-rail scan latch first multiplexer 5434, a fourth stage second dual-rail scan latch second multiplexer 5435, a fourth stage second dual-rail scan latch third multiplexer 5436.

In a typical test scan mode, the data transmission path of the asynchronous scan chain circuit just follow the path described in FIG. 2. First of all, the fourth stage first dual-rail scan latch 542 receives a scan handshake protocol input signal (Scan.Ack.i) via the fourth stage first dual-rail scan latch first multiplexer 5424 and transmit it to both the fourth stage first dual-rail scan latch first Muller C 5421 and the fourth stage first dual-rail scan latch second Muller C 5422 after outputting its two scan output signal (SO.t, SO.f).

The outputs of the third stage first dual-rail scan latch first Muller C 5321 and the third stage first dual-rail scan latch second Muller C 5322 are led to the input terminal of the fourth stage first dual-rail scan latch first Muller C 5421 and the fourth stage first dual-rail scan latch second Muller C 5422 via the fourth stage first dual-rail scan latch second multiplexer 5425 and the fourth stage first dual-rail scan latch third multiplexer 5426. Then the output of the fourth stage first dual-rail scan latch XNOR GATE 5423 is distributed into two signals, one is transmitted to the third stage first dual-rail scan latch first multiplexer 5324 as the scan hand shake protocol input signal, the other is transmitted to the input terminal of the fourth stage Muller C 541. The output signal of the fourth stage second dual-rail scan latch XNOR GATE 5433 is also led to the input terminal of the fourth stage Muller C 541, then the output of the fourth stage Muller C 541 is transmitted to the input terminal of the third stage first dual-rail scan latch first multiplexer 5324 as the functional handshake protocol input signal.

Then, gradually, the fourth stage second dual-rail scan latch 543 outputs a state signal to the third stage first dual-rail scan latch 532 and receives its handshake protocol input signal. The third stage second dual-rail scan latch 533 outputs a state signal to the fourth stage second dual-rail scan latch 543 and receives its handshake protocol input signal. The second stage second dual-rail scan latch 523 outputs a state signal to the third stage second dual-rail scan latch 533 and receives its handshake protocol input signal. The first stage first dual-rail scan latch 513 outputs a state signal to the second stage second dual-rail scan latch 523 and receives its handshake protocol input signal. The second stage first dual-rail scan latch 521 outputs a state signal to the first stage second dual-rail scan latch 513 and receives its handshake protocol input signal. The first stage first dual-rail scan latch 511 outputs a state signal to the second stage first dual-rail scan latch 522 and receives its handshake protocol input signal. The first stage first dual-rail scan latch 511 outputs a state signal after receiving a scan data input signal.

In summary, the present invention employs multiplexer to convert the transmission path between the normal function mode and the test scan mode, and uses handshake protocol between each two of the sequential elements in the asynchronous scan chain circuit as its transmission structure of the scan chain. Therefore, unlike previous DFT, the scan chain design for dual-rail asynchronous circuits does not require any clock in scan mode, which is a truly asynchronous DFT.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A scan chain circuit operated according to a handshake protocol signal, and comprising:
plural sequentially serially connected stage module circuits, which are alternatively connected in a connecting state under a functional mode and selectively connected at plural levels under a test scan mode, and each of which has:
an output terminal providing a handshake protocol output signal for a subsequent one of the stage module circuits;
an input terminal coupled to the output terminal of a preceding one of the stage module circuits under the functional mode; and
the plural levels.

2. A scan chain circuit according to claim 1, wherein each of the plural stage module circuits further comprises a 3-level unit circuit having a Muller C element having a first input terminal and a second input terminal, a first dual rail scan latch having an output terminal connected to the first input terminal of the Muller C element, and a second dual rail scan latch having an output terminal connected to the second input terminal of the Muller C element.

3. A scan chain circuit according to claim 2 further comprising plural combinational logic circuits respectively coupled between two adjacent ones of the plural stage module circuits, wherein each of the plural combinational logic circuits receives an output signal from one of the first and the second dual rail scan latches of a preceding one of the two adjacent stage module circuits to provide an input signal for one of the first and the second dual rail scan latches of a subsequent one of the two adjacent stage module circuits.

4. A scan chain circuit according to claim 2, wherein the handshake protocol output signal includes a handshake protocol output signal under the functional mode and a handshake protocol output signal under the test scan mode, and each of the first and the second dual rail scan latches further comprises:
two Muller C elements, each of which has a first input terminal, a second input terminal and an output terminal;
a first, a second and a third multiplexers, each of which has a first input terminal receiving a first input signal, a second input terminal receiving a second input signal, a scan enable terminal receiving an enable input signal and an output terminal transmitting an output signal, wherein all the first, the second and the third multiplexers use the respective received first input signals as the respective output signals when the respective received enable input signals are 0, all the first, the second and the third multiplexers use the respective received second input signals as the respective output signals when the respective received enable input signals are 1, the output terminal of the first multiplexer is coupled to the first input terminals of the two Muller C elements, and the output terminals of the second and the third multiplexers are respectively coupled to the second input terminals of the two Muller C elements; and
an exclusive-NOR gate having an input terminal coupled to the output terminals of the two Muller C elements of the first dual rail scan latch, and an output terminal providing the handshake protocol output signal under the test scan mode and coupled to the first input terminal of the Muller C element of the 3-level unit circuit and the second input terminal of the first multiplexer of one of the first and the second dual rail scan latches of the preceding one of the plural stage module circuits.

5. A scan chain circuit according to claim 4, wherein the handshake protocol signal includes a handshake protocol signal under the functional mode and a handshake protocol signal under the test scan mode, the first and the second input signals of the first multiplexer respectively are the handshake protocol signal under the functional mode and the handshake protocol signal under the test scan mode, the first and the second input signals of the second multiplexer respectively are a data true input signal under the functional mode and a scan true input signal under the test scan mode, and the first and the second input signals of the third multiplexer respectively are a data false input signal under the functional mode and a scan false input signal under the test scan mode.

6. A scan chain circuit according to claim 4 being operated in the functional mode when the scan enable signals are 0 and being operated in the test scan mode when the scan enable signals are 1.

7. A scan chain circuit according to claim 2, wherein the first and the second dual rail scan latches of the 3-level unit circuit of each of the plural stage module circuits receive the handshake protocol output signal provided from the subsequent one of the plural stage module circuits.

8. A scan chain circuit according to claim 2, wherein each of the first and the second dual rail scan latches has a first and a second input terminals, each of the first input terminals of the first and the second dual rail scan latches receives a data input signal, and each of the second input terminals of the first and the second dual rail scan latches receives a scan input signal.

9. A scan chain circuit according to claim 1, wherein each of the plural stage module circuits generates a state data according to the respective received handshake protocol output signals and shifts the respective state data to the preceding one of the plural stage module circuits under the functional mode, and the state data of a specific one of the plural stage module circuits is shifted to one of the plural levels of one of two stage module circuits adjacently connected to the specific stage module circuit under the test scan mode.

10. A scan chain circuit according to claim 1 being embedded in a chip.

11. A scan chain circuit according to claim 1 receiving an input signal and the handshake protocol signal and providing an output signal according to the input signal and the handshake protocol signal.

12. A scan chain circuit receiving a handshake protocol signal, and comprising:
plural sequentially serially connected stage module circuits, each of which has:
an output terminal providing a handshake protocol output signal for a subsequent one of the stage module circuits;
an input terminal coupled to the output terminal of an antecedent one of the stage module circuits under the functional mode; and
the plural levels.

13. A scan chain circuit according to claim 12 further comprising plural combinational logic circuits, wherein each of the plural stage module circuits further comprises a first and a second level circuits and a first and a second dual rail scan latches, the plural combinational logic circuits are respectively coupled between two adjacent ones of the plural stage module circuits, and each of the plural combinational logic circuits receives an output signal from one of the first and the second dual rail scan latches of an antecedent one of the two adjacent stage module circuits and provides an input signal for one of the first and the second dual rail scan latches of a subsequent one of the two adjacent stage module circuits.

14. A scan chain circuit according to claim 13, wherein each of the plural stage module circuits further comprises a Muller C element having a first input terminal, a second input terminal and an output terminal providing the respective handshake protocol output signal for the antecedent one of the stage module circuits.

15. A scan chain circuit according to claim 14, wherein the first level circuit is a first dual rail scan latch having an output terminal connected to the first input terminal of the Muller C element.

16. A scan chain circuit according to claim 14, wherein the second level circuit is a second dual rail scan latch having an output terminal connected to the second input terminal of the Muller C element.

17. A scan chain circuit, comprising:
plural stage module circuits, each of which provides a handshake protocol output signal for a preceding one of the plural stage module circuits.

18. A scan chain circuit according to claim 17 being operated according to a handshake protocol signal.

19. A scan chain circuit according to claim 17, wherein the plural stage module circuits are sequentially connected.
